(19) United States
(12) Patent Application Publication
(10) Pub. No.: US 2007/0164660 A1
(43) Pub. Date: Jul. 19, 2007

(54) DUAL-EMISSION ORGANIC ELECTROLUMINESCENT DEVICE

(75) Inventors: Min-Chieh Hu, Tainan County (TW); Chun-Yi Chiu, Taoyuan County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORP., Hsinchu (TW)

(21) Appl. No.: 11/549,743

(22) Filed: Oct. 16, 2006

(30) Foreign Application Priority Data
Jan. 19, 2006 (TW) 95102036

(51) Int. Cl. H01J 1/62

(52) U.S. Cl. 313/500

(57) ABSTRACT

A dual-emission organic electroluminescent device. The device comprises a substrate with a display region and a seal region, a plurality of bottom-emission organic light emitting diode pixel arrays, and a plurality of top-emission organic light emitting diode pixel arrays. The bottom-emission and top-emission organic light emitting diode pixel arrays are disposed coplanarly on the display region of the substrate arranged alternately.

### BACKGROUND OF THE INVENTION

1. Field of the Invention

The invention relates to an organic electroluminescent device, and more particularly to a dual-emission organic electroluminescent device.

2. Description of the Related Art

Many types of flat panel display have been and are currently being developed. One popular type of flat panel display is a liquid crystal display (LCD). Liquid crystal displays (LCDs) generally perform well, but have somewhat narrow viewing angles, relatively slow response times, and require backlight. Consequently, LCDs are not at their best for high-speed image animation and consume additional energy powering the backlight. In addition, large LCDs are difficult to produce.

Organic light emitting diode (OLED) displays have been developed to address the disadvantages of LCDs. Unlike LCDs which modulate light generated by their backlight systems, OLED displays emit light via an array of OLED-based pixels. Organic electroluminescent elements are self-emitting, and highly luminous, with wider viewing angle, faster response speed, and a simple fabrication process, making them the display industry of choice.

With the progress of information technology and the electronic products, it is necessary to not only improve display response time and resolution but also development of various functions and applications. For example, portable electronic products, which employ dual-emission display devices, such as collapsible mobile phones, PDAs, and notebooks, are called for. Dual-emission display devices have the advantages of extended screen space and display of multiple images. Accordingly, there has been an increasing demand for organic electroluminescent devices which display images on both sides (dual-emission organic electroluminescent device).

However, most conventional dual-emission OLED display, are assembled from two single-emission organic electroluminescent devices as shown in FIG. 1. The organic electroluminescent devices 11 and 12 are individually packaged and then assembled back-to-back, comprising the dual-screen display set 10.

In the structures described, the dual-display devices require individual packaging before being combined, size, manufacturing, cost, weight and thickness of the assembly in current dual-screen display devices are not improved.

Another dual-screen organic electroluminescent device 100 has been provided as shown in FIG. 2. First and second organic electroluminescent elements 50 and 52 are respectively formed on a bottom substrate 60 and top substrate 62. Next, the bottom substrate 60 and top substrate 62 are combined by an adhesive, and an insulation layer 70 is formed between the first and second organic electroluminescent elements 50 and 52 to separate them. Light emitted from the organic electroluminescent elements 50 and 52 travels through the transparent substrates 60 and 62, which art as a display side.

Manufacturing cost and time of dual-screen organic electroluminescent device 100 is less than that of the dual-screen display set 10 shown in FIG. 1, however, thickness remains more than that of conventional single-emission organic electroluminescent device.

Therefore, it is necessary to develop a thinner dual-emission organic electroluminescent device.

### BRIEF SUMMARY OF THE INVENTION

Accordingly, an object of the invention is to provide a novel dual-emission organic electroluminescent device, without increasing vprocess complexity.

An exemplary embodiment of a dual emission organic electroluminescent device comprises a substrate with a display region and a seal region and a plurality of bottom-emission organic light emitting diode pixel arrays and a plurality of top-emission organic light emitting diode pixel arrays within the display region.

Particularly, the bottom-emission and top-emission organic light emitting diode pixel arrays are disposed coplanarly on the substrate and arranged alternately.

According to another exemplary embodiment of the invention, the dual emission organic electroluminescent device further comprises a sealing case, an adhesive and a desiccant. The adhesive disposed on the substrate within the seal region to bond the sealing case on the substrate. The desiccant is disposed within the seal region to surround the display region.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is cross sections of a conventional dual-screen display set.

FIG. 2 is a cross section of another conventional dual-screen organic electroluminescent device.

FIGS. 3a to 3d are cross sections of the process of manufacturing a dual-emission organic electroluminescent device according to an embodiment of the invention.

FIGS. 4a and 4b show a location relationship between bottom-emission and top-emission organic light emitting diode pixel arrays according to embodiments of the invention.

FIG. 5 is a cross section of a dual-emission organic electroluminescent device according to an embodiment of the invention.

FIG. 6 is a cross section of a dual-emission organic electroluminescent device according to another embodiment of the invention.

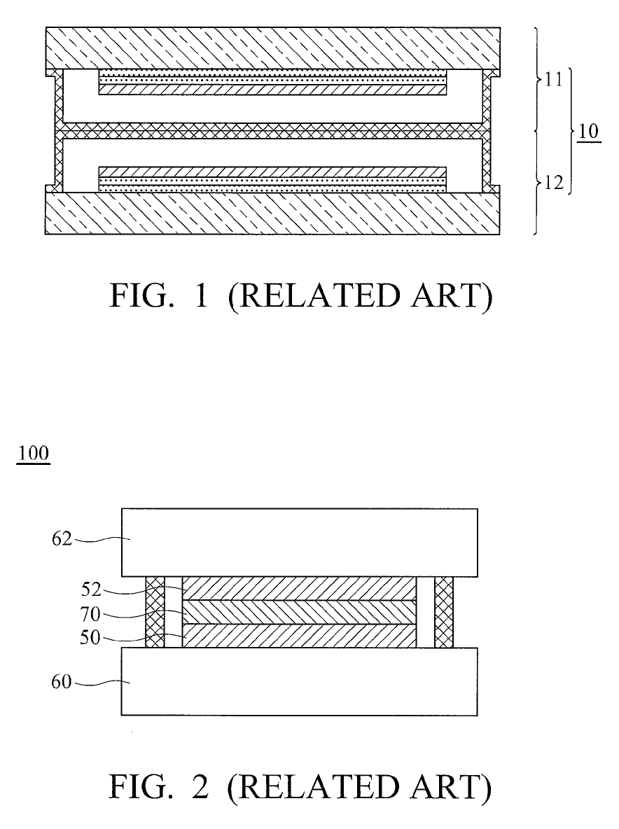

### DETAILED DESCRIPTION OF THE INVENTION

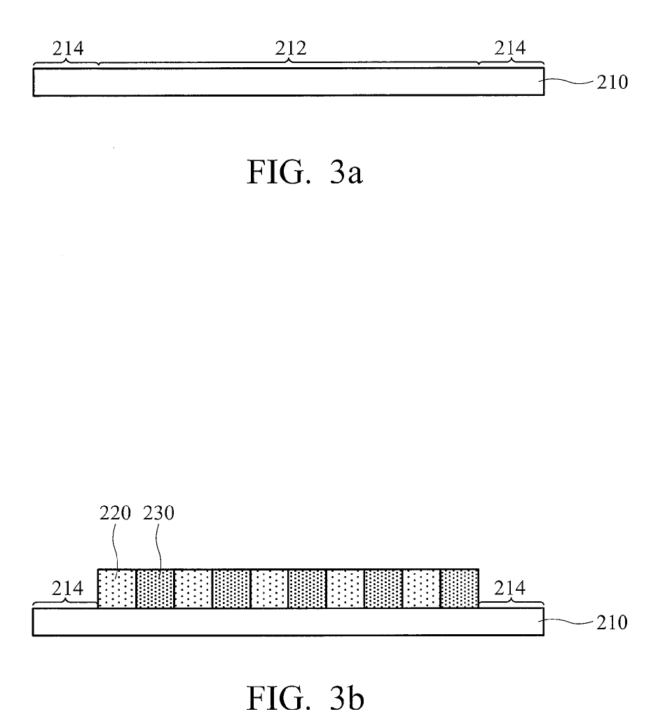

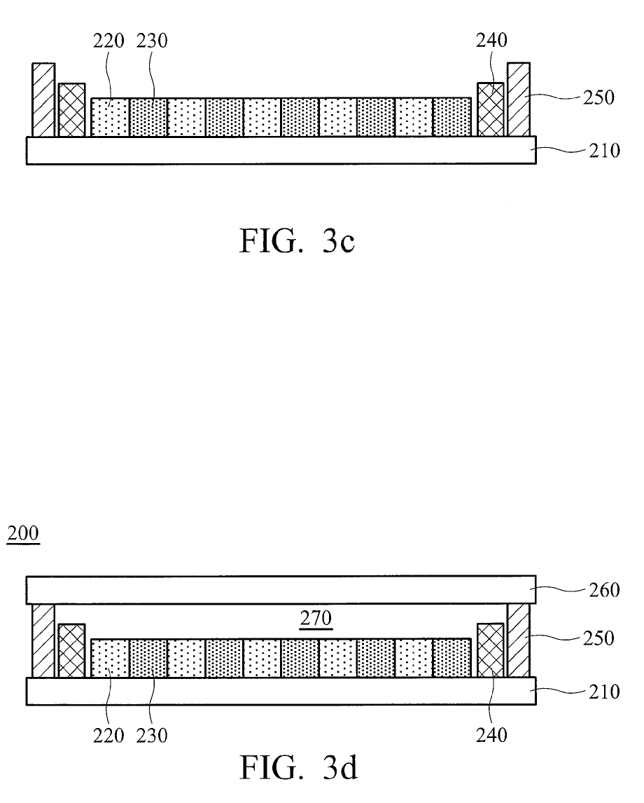

FIGS. 3a to 3b are sectional diagrams illustrating the manufacturing process of the dual-emission organic electroluminescent device 200 according to an embodiment of the invention.

First, referring to FIG. 3a, a substrate 210 with a display region 212 and a seal region 214 is provided, and can be a transparent substrate, such as glass, plastic, or ceramic substrate.

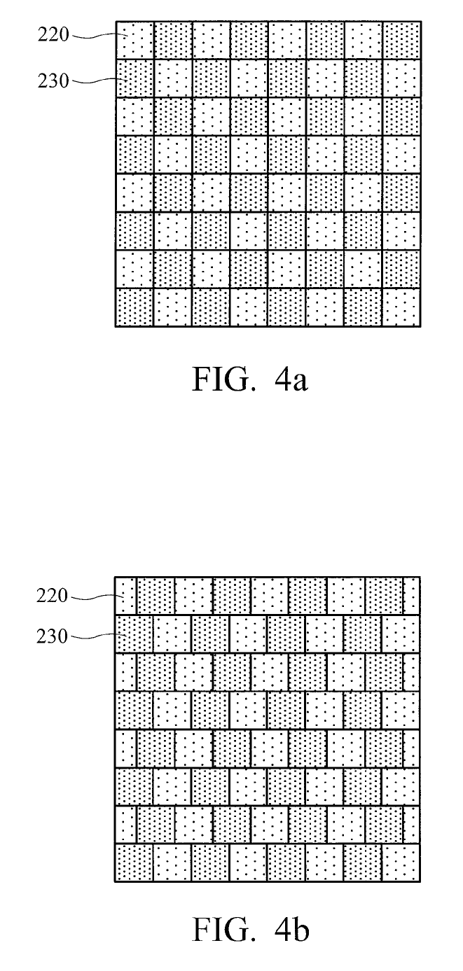

Next, referring to FIG. 3b, a plurality of bottom-emission organic light emitting diode pixel arrays 220 and a plurality of top-emission organic light emitting diode pixel arrays 230 are formed within the display region 212. It should be noted that the bottom-emission and top-emission organic light emitting diode pixel arrays must be disposed coplanarly on the substrate and arranged alternately, as shown in FIGS. 4a and 4b. Further, the display area of the plurality of bottom-emission organic light emitting diode pixel arrays 220 can be the same as that of the plurality of top-emission organic light emitting diode pixel arrays 230. In another embodiment, the display areas of the plurality of bottom-emission organic light emitting diode pixel arrays 220 can be different from that of plurality of top-emission organic light emitting diode pixel arrays 230. Moreover, the top-emission and bottom-emission organic light emitting diode pixel arrays can comprise small molecule-based organic light emitting diodes or polymer-based organic light emitting diodes.

According to an embodiment of the invention, the top-emission and bottom-emission organic light emitting diode pixel arrays can be active matrix organic light emitting diode pixel arrays, i.e. the substrate 210 is an active matrix substrate (a plurality of thin film transistors formed thereon). In another embodiment of the invention, the top-emission and bottom-emission organic light emitting diode pixel arrays can be passive matrix organic light emitting diode pixel arrays.

Next, referring to FIG. 3c, a desiccant 240 is formed on the substrate 210 within the seal region 214, surrounding the display region. Next, an adhesive 250 is formed on the substrate 210 within the seal region 214, surrounding the desiccant 240. Particularly, the desiccant 240 can be formed by deposition. Furthermore, the desiccant can be formed in advance and attached on the substrate or the sealing case. Suitable materials for the desiccant can be alkali or alkaline earth metal or compounds thereof. Herein, the choices for the adhesive 250 are unlimited, and can be photo sensitive adhesive, thermal-cured adhesive, UV-cured resin, or pressure sensitive adhesive.

Finally, referring to FIG. 3d, a sealing case 260 is bonded on the substrate 210 using the adhesive 250 to form a cavity 270, thus completing fabrication of the dual-emission organic electroluminescent device 200. Specifically, the sealing case has a transparency of more than 30% and can be glass or plastic substrate. Moreover, a filler (not shown) having a transparency of more than 30% can be further provided to fill the cavity 270, to absorb moisture and impurities.

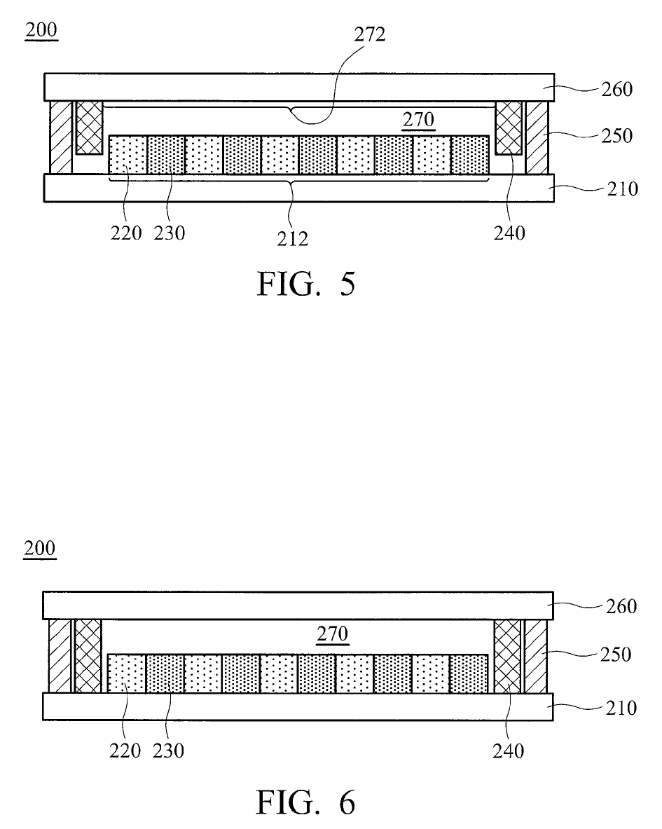

In some embodiments, referring to FIG. 5, the desiccant 240 can be disposed on the sealing case 260 over the seal region 214, surrounding the region 272 of the sealing case 260 corresponding to the display region 212 of the substrate 210. In another embodiment, referring to FIG. 6, the desiccant 240 can be disposed on the sealing case 260 and the substrate 210 simultaneously within the seal region 214 and surrounding the display region 212 of the substrate 210.

Accordingly, the dual-emission organic electroluminescent device of the invention is thinner, volume meeting the demands of the flat panel display market, resulting form the bottom-emission and top-emission organic light emitting diode pixel arrays are disposal coplanar on the substrate.

Since the desiccants are disposed around the bottom-emission and top-emission organic light emitting diode pixel arrays, seeping moisture and oxygen from the atmosphere can be absorbed by the desiccants, preventing electroluminescent layers decomposition.

Moreover, the adhesive and the organic light emitting diode pixel arrays are separated by the desiccant to prevent the adhesive diffusing into the organic light emitting diode pixel arrays.

While the invention has been described by way of example and in terms of preferred embodiment, it is to be understood that the invention is not limited thereto. To the contrary, it is intended to cover various modifications and similar arrangements (as would be apparent to that skilled in the art). Therefore, the scope of the appended claims should be accorded the broadest interpretation so as to encompass all such modifications and similar arrangements.

What is claimed is:

1. A dual emission organic electroluminescent device, comprising:
a substrate with a display region and a seal region; and
a plurality of bottom-emission organic light emitting diode pixel arrays and a plurality of top-emission organic light emitting diode pixel arrays within the display region,
wherein the bottom-emission and top-emission organic light emitting diode pixel arrays are disposed coplanarly on the substrate and arranged alternately.

2. The device as claimed in claim 1, wherein display areas of the plurality of bottom-emission organic light emitting diode pixel arrays are the same as those of the plurality of top-emission organic light emitting diode pixel arrays.

3. The device as claimed in claim 1, wherein display areas of the plurality of bottom-emission organic light emitting diode pixel arrays are different from those of the plurality of top-emission organic light emitting diode pixel arrays.

4. The device as claimed in claim 1, wherein the substrate is a glass substrate, a plastic substrate, or a ceramic substrate.

5. The device as claimed in claim 1, wherein the top-emission and bottom-emission organic light emitting diode pixel arrays comprise small molecule-based organic light emitting diodes.

6. The device as claimed in claim 1, wherein the top-emission and bottom-emission organic light emitting diode pixel arrays comprise polymer-based organic light emitting diodes.

7. The device as claimed in claim 1, wherein the top-emission and bottom-emission organic light emitting diode pixel arrays comprise active matrix organic light emitting diode pixel arrays.

8. The device as claimed in claim 1, wherein the top-emission and bottom-emission organic light emitting diode pixel arrays comprise passive matrix organic light emitting diode pixel arrays.

9. The device as claimed in claim 1, further comprising:
a sealing case; and
an adhesive disposed on the substrate within the seal region for bonding the sealing case on the substrate

10. The device as claimed in claim 9, wherein the sealing case has a transparency of more than 30%.

11. The device as claimed in claim 9, wherein the sealing case comprises glass substrate or a plastic substrate.

12. The device as claimed in claim 9, further comprising a desiccant within the seal region surrounding the display region.

13. The device as claimed in claim 12, wherein the desiccant is formed on by deposition.

14. The device as claimed in claim 12, wherein the desiccant is attached on the substrate or the sealing case.

15. The device as claimed in claim 12, wherein the desiccant is attached on the sealing case.

16. The device as claimed in claim 12, wherein the desiccant is formed on the substrate within the seal region surrounding the display region.

17. The device as claimed in claim 12, wherein the desiccant is formed on the sealing case within the seal region surrounding the display region.

18. The device as claimed in claim 12, wherein the desiccant is formed on the sealing case and the substrate within the seal region surrounding the display region.
